(19) United States
(12) Patent Application Publication
(10) Pub. No.: US 2025/0164287 A1
(43) Pub. Date: May 22, 2025

(54) SYSTEM AND METHOD FOR TRAILER TANDEM LOCK-STATE DETECTION

(71) Applicant: R.A. PHILLIPS INDUSTRIES, INC., Irvine, CA (US)

(72) Inventor: Marquis D. Doyle, Boone, NC (US)

(21) Appl. No.: 18/949,427

(22) Filed: Nov. 15, 2024

Related U.S. Application Data
(60) Provisional application No. 63/599,736, filed on Nov. 16, 2023.

(51) Int. Cl. G01D 5/20; B62D 63/06; B62D 63/08

(52) U.S. Cl. CPC G01D 5/20; B62D 63/061; B62D 63/08

(57) ABSTRACT

A tandem lock-state detector of a vehicle having a sliding tandem includes an inductive element in a cavity of a lock pin of the sliding tandem, a driving circuit configured to generate a drive signal for driving the inductive element, a sensing circuit configured to sense a parameter of the inductive element, and a processor configured to detect a locked state or an unlocked state of the lock pin based on a level of the parameter.

### CROSS-REFERENCE TO RELATED APPLICATION(S)

This application claims priority to, and the benefit of, U.S. Provisional Application No. 63/599,736 (“SYSTEM AND METHOD FOR TRAILER TANDEM LOCK-STATE DETECTION”), filed on Nov. 16, 2023, the entire content of which is incorporated herein by reference.

### FIELD

Aspects of the present disclosure relate to trailer tandem systems and methods of using the same.

### BACKGROUND

Most semi-tractor trailers in the US have sliding tandems, which are a set of 8 wheels on two axles that are moveably coupled to the rear underside of the trailer. The tandems can slide along a track under the trailer to allow for the distribution of weight of the trailer to be adjusted to support better ride control, handling, turning radius, and legal compliance.

During the tandem repositioning process, the tandem lock pins (usually four per tandem) must be moved to the unlocked state. Once the tandem is properly repositioned, the tandem lock pins must then be moved back to the locked state prior to normal driving.

In the related art, the unlocking and locking process may be troublesome and unreliable due to the locking pins getting jammed during unlocking and blocked during locking. As a result of this uncertain lock/unlock process, the driver must visually inspect all four pins to verify their state before repositioning or driving. This visual inspection could result in multiple trips between the cab and around the tandem by the driver, resulting in time spent and potential safety issues.

The above information disclosed in this Background section is only for enhancement of understanding of the background of the invention and therefore it may contain information that does not form the prior art that is already known to a person of ordinary skill in the art.

### SUMMARY

Aspects of embodiments of the present invention are directed to a tandem locking system of a vehicle (e.g., a trailer or chassis) including a tandem lock-state detector, which is configured to detect a state of a tandem lock pin and to communicate this state information to a user (e.g., truck driver). The system includes one or more tandem lock pins and a tandem lock-state detector for determining the lock/unlocked state of each of the lock pins. In some embodiments, each lock pin is embedded with an inductor that is driven by an oscillating signal and thus generates a changing magnetic field, which can induce eddy currents in the guide tube and conductive metal frames of the sliding tandem and trailer. The intensity of these currents, and thus the power dissipated by them, changes as the lock pin moves through a hole in the frame of the sliding tandem. In some embodiments, the tandem lock-state detector is capable of detecting this change and making a determination as to whether the lock pin is in a locked or unlocked state accordingly.

The tandem lock-state detector provides real-time lock state information regarding each of the tandem lock pins to a driver or autonomous vehicle, eliminating the need for manual inspection. This enhances safety and operational efficiency.

According to some embodiments of the present disclosure, there is provided a tandem lock-state detector of a vehicle having a sliding tandem, the tandem lock-state detector including: an inductive element in a cavity of a lock pin of the sliding tandem; a driving circuit configured to generate a drive signal for driving the inductive element; a sensing circuit configured to sense a parameter of the inductive element; and a processor configured to detect a locked state or an unlocked state of the lock pin based on a level of the parameter.

In some embodiments, the tandem lock-state detector further includes a capacitor electrically coupled in parallel to the inductive element.

In some embodiments, the drive signal is an oscillating signal with a regulated oscillation amplitude.

In some embodiments, the parameter is a power consumed by the inductive element.

In some embodiments, the cavity of the lock pin is exposed to an outside of the lock pin and is configured to accommodate the inductive element, and wherein the lock pin has a passageway for accommodating conductive wires from the driving circuit to the inductive element.

In some embodiments, the inductive element extends along a longitudinal direction of the locking pin.

In some embodiments, the lock pin is configured to extend through a hole of the sliding tandem in the locked state and to be retracted from the hole in the unlocked state.

In some embodiments, the inductive element is positioned in the lock pin to overlap, in a plan view, frame rails of the sliding tandem in the locked state and to not overlap, in the plan view, the frame rails of the sliding tandem in the unlocked state.

In some embodiments, eddy currents induced in metal surrounding the lock pin by magnetic field lines extending from the inductive element in the locked state are greater in intensity than those induced in the metal surrounding the lock pin by the magnetic field lines in the unlocked state.

In some embodiments, the processor is configured to detect the locked state of the lock pin in response to the level of the parameter being greater than a threshold, and to detect the unlocked state of the lock pin in response to the level of the parameter being less than or equal to the threshold.

In some embodiments, the lock pin is coupled to an actuator configured to move the lock pin along a transverse direction of the sliding tandem and through a guide tube and a hole of the sliding tandem, the guide tube surrounding the hole.

According to some embodiments of the present disclosure, there is provided a tandem locking system of a vehicle having a sliding tandem, including: a lock pin configured to lock the sliding tandem to a trailer frame of the vehicle; a tandem lock-state detector including: an inductive element in a cavity of the lock pin; a driving circuit configured to generate a drive signal for driving the inductive element; a sensing circuit configured to sense a parameter of the inductive element; and a processor configured to detect a locked state or an unlocked state of the lock pin based on a level of the parameter.

In some embodiments, the drive signal is an oscillating signal with a regulated oscillation amplitude, and wherein the parameter is a power consumed by the inductive element.

In some embodiments, the tandem locking system further including: an actuator coupled to the lock pin and configured to move the lock pin through a guide tube of the sliding tandem in response to a user input, wherein the actuator includes at least one of a rotating shaft actuator, an air bag actuator, or a lever arm actuator.

In some embodiments, the lock pin is configured to extend through a hole of the sliding tandem in the locked state and to be retracted from the hole in the unlocked state, and wherein the inductive element is positioned in the lock pin to overlap, in a plan view, frame rails of the sliding tandem in the locked state and to not overlap, in the plan view, the frame rails of the sliding tandem in the unlocked state.

In some embodiments, eddy currents induced in metal surrounding the lock pin by magnetic field lines extending from the inductive element in the locked state are greater in intensity than those induced in the metal surrounding the lock pin by the magnetic field lines in the unlocked state, and wherein the processor is configured to detect the locked state of the lock pin in response to the level of the parameter being greater than a threshold, and to detect the unlocked state of the lock pin in response to the level of the parameter being less than or equal to the threshold.

According to some embodiments of the present disclosure, there is provided a method of detecting a locked state of a sliding tandem of a vehicle, including: generating, by a tandem lock-state detector of the vehicle, a drive signal for driving an inductive element in a cavity of a lock pin of the sliding tandem; sensing, by the tandem lock-state detector, a parameter of the inductive element; and detecting, by the tandem lock-state detector, the locked state or an unlocked state of the lock pin based on a level of the parameter.

In some embodiments, the drive signal is an oscillating signal with a regulated oscillation amplitude, and wherein the parameter is a power consumed by the inductive element.

In some embodiments, the detecting the locked state or the unlocked state includes: detecting the locked state of the lock pin in response to the level of the parameter being greater than a threshold.

In some embodiments, the detecting the locked state or the unlocked state includes: detecting the unlocked state of the lock pin in response to the level of the parameter being less than or equal to a threshold.

### BRIEF DESCRIPTION OF THE DRAWINGS

In order to facilitate a fuller understanding of the present invention, reference is now made to the accompanying drawings, in which like elements are referenced with like numerals. These drawings should not be construed as limiting the present invention, but are intended to be illustrative only.

FIG. 1 illustrates a vehicle utilizing a tandem locking system, according to some embodiments of the present disclosure.

FIG. 2 illustrates a plan view of the sliding tandem of the vehicle and the tandem locking system, according to some embodiments of the present disclosure.

FIGS. 3A and 3B respectively illustrate a perspective view and a top view of the tandem lock pin embedded with an inductive element, according to some embodiments of the present disclosure.

FIG. 3C illustrates a cross-sectional view of the tandem lock pin taken along the line A-A′ of FIG. 3B, according to some embodiments of the present disclosure.

FIG. 4A and 4B illustrate partial perspective views of the trailer frame and the lock pin when in locked state and unlocked state, respectively, according to some embodiments of the present disclosure.

FIG. 5 is a block diagram of the tandem lock-state detector of the tandem locking system, according to some embodiments of the present disclosure.

FIG. 6 illustrates a process of detecting a locked state of the sliding tandem, according to some embodiments of the present disclosure.

### DETAILED DESCRIPTION

The detailed description set forth below in connection with the appended drawings is intended as a description of illustrative embodiments of a tandem locking system including a tandem lock-state detector in accordance with the present invention, and is not intended to represent the only forms in which the present invention may be implemented or utilized. The description sets forth the features of the present invention in connection with the illustrated embodiments. It is to be understood, however, that the same or equivalent functions and structures may be accomplished by different embodiments that are also intended to be encompassed within the spirit and scope of the present invention. As denoted elsewhere herein, like element numbers are intended to indicate like elements or features.

Most semi-tractor trailers have sliding tandems, which are a set of eight wheels on two axles near the back of the trailer. These tandems slide to allow for the distribution of weight of the trailer to be adjusted to support better ride control, handling, turning radius, and legal compliance. During the tandem repositioning process, the tandem lock pins need to be moved to the unlocked state. Once the tandem is properly repositioned, the tandem lock pins need then be moved back to the locked state prior to driving.

The unlocking and locking process may be troublesome and unreliable due to the locking pins getting jammed during unlocking and blocked during locking. As a result of this uncertain lock/unlock process, the driver has to visually inspects all of the lock pins to verify their state before repositioning or driving. This visual inspection could result in multiple trips between the cab and around the tandem by the driver, resulting in time spent and potential safety issues.

Aspects of embodiments of the present invention are directed to a tandem locking system including a tandem lock-state detector that is capable of detecting and communicating the lock/unlock state of each of the tandem lock pins before, during and after a tandem repositioning operation to the truck driver or to an autonomous vehicle. This allows the driver to determine the lock state of the tandem lock pins without having to exit the cab and visually inspect each lock pin. This can result in improved safety and time savings for the driver and fleet operator. Further, when combined with a lock pin actuation mechanism controlled by the driver in the cab and a tandem position determination system, there is no need to exit the cab during an entire tandem repositioning operation. This capability also facilitates a fully automated tandem repositioning operation by an autonomous tractor/trailer.

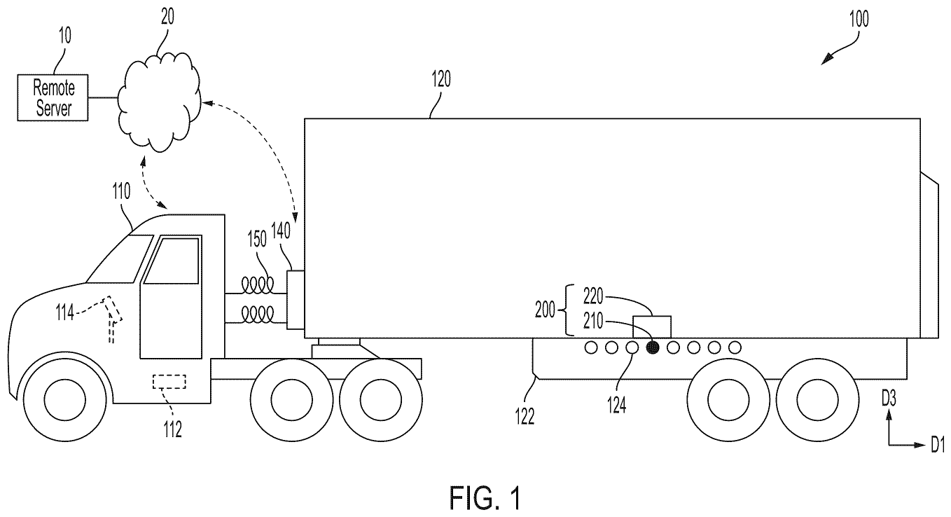

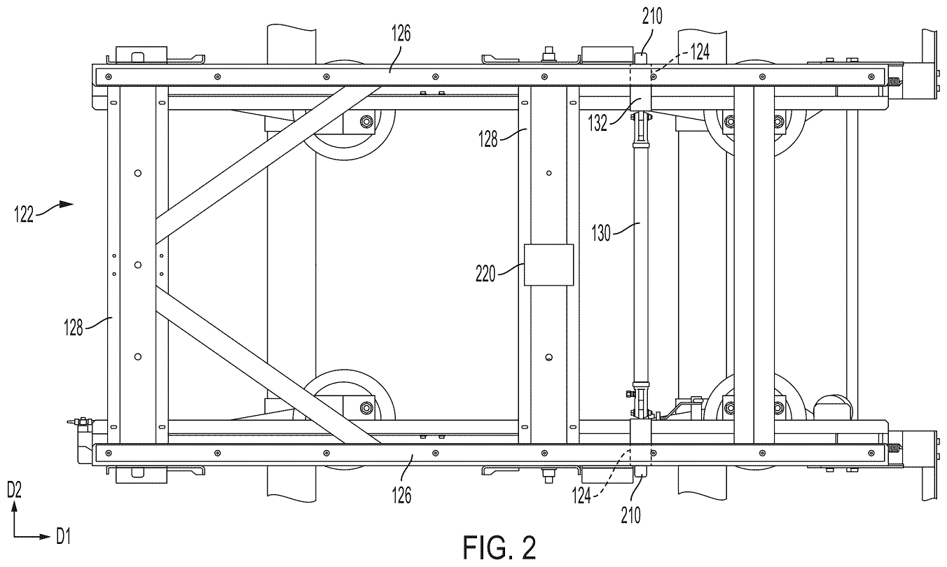

FIG. 1 illustrates a vehicle 100 utilizing the tandem locking system 200, according to some embodiments of the present disclosure. FIG. 2 illustrates a plan view of the sliding tandem 122 of the vehicle 100 and the tandem locking system 200, according to some embodiments of the present disclosure.

As illustrated in FIG. 1, the vehicle (e.g., the heavy duty vehicle) 100 includes a tow vehicle (also referred to as a truck or tractor) 110 and a trailer 120. The tow vehicle 110 provides the necessary power and control for the trailer 120 when attached to the tow vehicle 110. Hereinafter, the term “trailer” may refer to a walled/covered semi-trailer, a flatbed trailer, or a chassis.

The trailer 120 has a sliding tandem 122 with a set of wheels (e.g., eight wheels) on two axles near the rear of the trailer 120 that can slide along the length of the trailer 120 (e.g., in the first direction D1) along a track in the trailer's frame to adjust weight distribution for optimal ride control, handling, turning radius, and legal compliance.

Referring to FIGS. 1-2, according to some embodiments, the tandem locking system 200 includes a plurality of (e.g., four) tandem lock pins (also referred to simply as lock pins) 210 and a tandem lock-state detector 220. The lock pins 210 secure the sliding tandem 122 in place by engaging with holes 124 in the trailer frame 126. The lock pin typically extends through these holes to lock the tandem in a fixed position, preventing any unintended movement during transit. During repositioning, the lock pins 210 are moved to an unlocked state to allow sliding of the tandem 122 and then locked again to secure the tandem 122.

The lock pins 210 can be actuated manually or with actuators 130 to slide through guide tubes 132 and extend through corresponding holes 124. The guide tube 132, which is rigidly attached to the frame of the sliding tandem 122, surrounds the hole 124 and guides the passage of the lock pin 210 through the hole 124. The actuators 130 used to engage the lock pin 210 of the tandem locking system 200 can include various mechanisms such as rotating shaft actuators, airbag actuators, lever arm actuators, or the like. Each actuator type serves the purpose of moving the lock pin 210 into the locked or unlocked state by applying a force that either extends or retracts the lock pin 210 through the corresponding hole 124 in the tandem frame and trailer frame 126. Rotating shaft actuators may use a rotating cam mechanism connected to a shaft, which translates rotational motion into linear motion to move the lock pin 210. Airbag actuators operate by inflating or deflating a rubber airbag, causing the lock pin 210 to retract or extend. Lever arm actuators involve a mechanical lever that can be manually or automatically engaged to move the lock pin 210.

In some examples, the tandem lock-state detector 220 may be attached to one of the tandem cross members (e.g., cross bars or I-beams) 128 that span the width of the sliding tandem 122 (e.g., along a second direction D2 that crosses the first direction D1). However, embodiments of the present disclosure are not limited thereto, and the tandem lock-state detector 220 may be positioned at any suitable location (e.g., at the undercarriage of the trailer 120, etc.). Further, the tandem lock-state detector 220 may be attached to the trailer 120 or the sliding tandem 122 by any suitable means, such as welding, fastening (e.g., via rivets/screws), adhering via an adhesive, and/or the like.

In some embodiments, each of the lock pins 210 is embedded with an inductive element (e.g., an inductor) that generates a changing magnetic field. The tandem lock-state detector 220 is configured to determine the lock/unlock state of each lock pin 210 based on the power dissipated by eddy currents induced by the changing magnetic fields in the portions of the conductive metal frame and guiding tube 132 of the sliding tandem 122 and the trailer track rail 126 that are in the vicinity of the corresponding lock pin 210.

Referring again to FIG. 1, the vehicle 100 is equipped with a communication system that enables data flow between the various components of the tow vehicle 110 and the trailer 120. The communication system includes a telematics gateway module 140 and a harness 150. The telematics gateway module 140 may be located at the front side of the trailer 120 (e.g., at the nose box of the trailer 120). The telematics gateway module 140 is configured to be electrically coupled to an electrical system of the tow vehicle 110 via the harness 150. That is, the telematics gateway module 140 facilitates the transfer of electrical signals between the tow vehicle 110 and the trailer 120, enabling bi-directional communication.

The communication system allows the tandem lock-state detector 220 to communicate with various electronic devices at the tow vehicle 110 including a vehicle communication system (VCS) 112 and a human-machine interface (HMI) 114. The VCS 112 may be part of a computer network in which vehicles and roadside units are the communicating nodes, providing each other with information, such as safety warnings and traffic information. The HMI 114 may act as the primary point of interaction between the driver and the vehicle's various systems, allowing them to control functions, monitor vehicle status, receive alerts, and access information through a user-friendly display, typically including a touchscreen, buttons, and dials, which helps the driver operate the truck more efficiently and safely by presenting relevant information in a clear and intuitive way.

The tandem lock-state detector 220 may transmit the locking pin state information to the telematics gateway module 140 over controller area network (CAN), WiFi, Bluetooth, RS232/485, power line carrier (PLC) or any other suitable protocol, so it's data can be transmitted to the cab driver (via the HMI 114) or autonomous truck controller to make actionable decisions from the state of the locking pins 210. In some examples, the telematics gateway module 140 may also communicate the locking state via a cellular connection or a broadband (e.g., Wi-Fi) connection to an external server (e.g., a remote server 10 on the cloud 20) for monitoring of the trailer 120. This may allow a driver or a dispatcher, for example, to confirm the proper locking of the tandem 122.

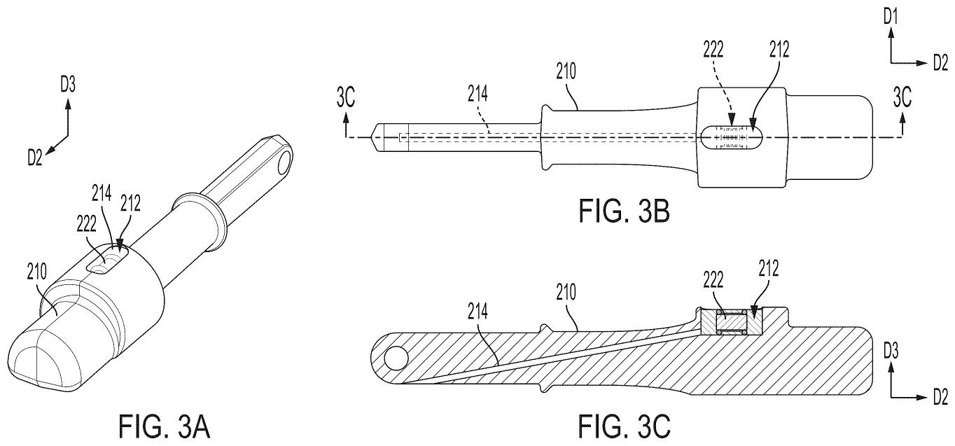

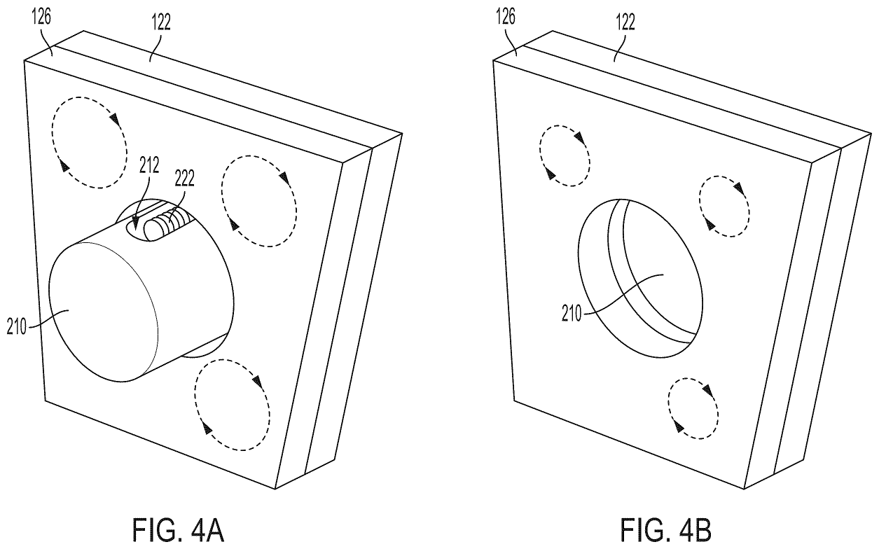

FIGS. 3A and 3B respectively illustrate a perspective view and a top view of the tandem lock pin 210 embedded with an inductive element, according to some embodiments of the present disclosure. FIG. 3C illustrates a cross-sectional view of the tandem lock pin 210 taken along the line A-A′ of FIG. 3B, according to some embodiments of the present disclosure. FIG. 4A and 4B illustrate partial perspective views of the trailer frame 126 and the lock pin 210 when in locked state and unlocked state, respectively, according to some embodiments of the present disclosure.

Referring to FIGS. 3A-3C, in some embodiments, the tandem lock pin 210 includes an inductive element (e.g., an inductor or inductor coil) 222 embedded within a cavity 212 of the lock pin 210. The lock pin 210 may also define a through-hole (or passageway; e.g., a ⅛″ through hole) 214 extending through the length of the lock pin 210 for accommodating (e.g., routing) conductive wires from a driving circuit to the inductive element 222. The wiring may exit the body of the lock pin 210 at a point where the wiring is less likely to be damaged during the operation of the tandem locking system 200.

The cavity 212 for the inductive element 222 is designed to maintain the structural integrity of the lock pin while providing sufficient space for the inductive element 222 and the associated wiring. The placement of the inductive element 222 within the cavity 212 serves to protect the inductive element 222 from physical damage. By embedding the inductor within the lock pin and positioning the inductor away from areas that may experience mechanical impact or wear, the design ensures the longevity and reliability of the tandem locking system 200.

In some examples, a potting material 214 fills the cavity 212 of the lock pin 210 to encapsulate the inductive element 222 and the associated wiring. This material 214 provides mechanical protection to the inductive element 222, shielding it from physical damage and environmental factors such as moisture, dust, and vibration. The potting material 214 serves to ensure the longevity and reliability of the tandem locking system 200 by maintaining the integrity of the inductive element 222 and preventing any potential short circuits or electrical failures. The potting material 214 may be selected based on the dielectric properties, thermal stability, and mechanical strength. In some examples, the potting material 214 possesses a high dielectric strength to insulate the inductive element and wiring effectively. Additionally, the potting material 214 may exhibits thermal stability to withstand the temperature variations encountered during the operation of the trailer. The mechanical strength of the potting material 214 ensures that the potting material can endure the mechanical stresses and impacts that the lock pin 220 may experience during use. The potting material 214 may, for example, include resin (e.g., epoxy resin), a polyurethane compound, and/or the like. The application process of the potting material 214 may involve filling the cavity 212 of the lock pin 210 with the material in a liquid or semi-liquid state, allowing the material 214 to flow around the inductive element 222 and wiring. Once the cavity 212 is filled, the potting material 214 is cured to form a solid, protective encapsulation. This curing process can be achieved through various methods, such as heat curing, UV curing, room temperature curing, etc.

According to some embodiments, the cavity 212 and the inductive element 222 inside extend along the longitudinal axis of the lock pin 210 to increase (e.g., maximize) the interaction between the magnetic flux produced by the inductive element 222 and the surrounding metal structures of the tandem and trailer frames during the locking and unlocking process. However, embodiments of the present disclosure are not limited thereto, and the cavity 212 and the inductive element 222 may be oriented along a direction perpendicular to the longitudinal axis of the lock pin 210 (e.g., along the third direction D3).

In some embodiments, the cavity 212 of the lock pin 210 is positioned at the outer surface of the lock pin 210 so as to be exposed to the outside of the lock pin 210. This serves to further increase the interaction of the changing magnetic field produced by the inductive elements and the surrounding metal structure when in a locked state and to increase the contrast in the level of interaction between the locked and unlocked states.

Referring also to FIGS. 4A-4B, the inductive element 222 is configured to generate a changing magnetic field when driven by an oscillating drive signal, which induces eddy currents in the conductive metal frames of the trailer 120 and sliding tandem 122 (including the guide tube 132). The intensity of these eddy currents varies depending on the position of the lock pin 210, providing a reliable indicator of whether the pin is in a locked or unlocked state.

In some embodiments, the cavity 212 in the lock pin 210 is positioned near the end of the lock pin 210 that extends through the hole 124 in the trailer frame 126 when in the locked state. This placement ensures that the inductive element 222 is exposed to varying amounts of surrounding metal, depending on whether the lock pin 210 is in the locked or unlocked state. When the lock pin 210 is in the locked state (see, e.g., FIG. 4A), the inductive element 222 is surrounded by the metal of the trailer frame 126 and the sliding tandem frame and guide tube 132, resulting in higher eddy currents. When the lock pin 210 is in the unlocked state (see, e.g., FIG. 4B), the inductive element 222 is exposed to more free air, resulting in lower eddy currents. Accordingly, the difference in eddy currents resulting from the locked and unlocked lock pin states may serve as a reliable and sensitive parameter to indicate lock pin state. In some examples, the higher eddy current caused by more metal in proximity to the inductor core 222 in the locked state uses more power to maintain resonance with the inductor element 222. This difference in the used power between the two lock pin states may be sufficient to act as a suitable indicator of actual locking pin state. However, embodiments of the present disclosure are not limited thereto. That is, depending on the inductor orientation and/or size, an inductor parameter other than eddy current may be a signifier of locking pin state.

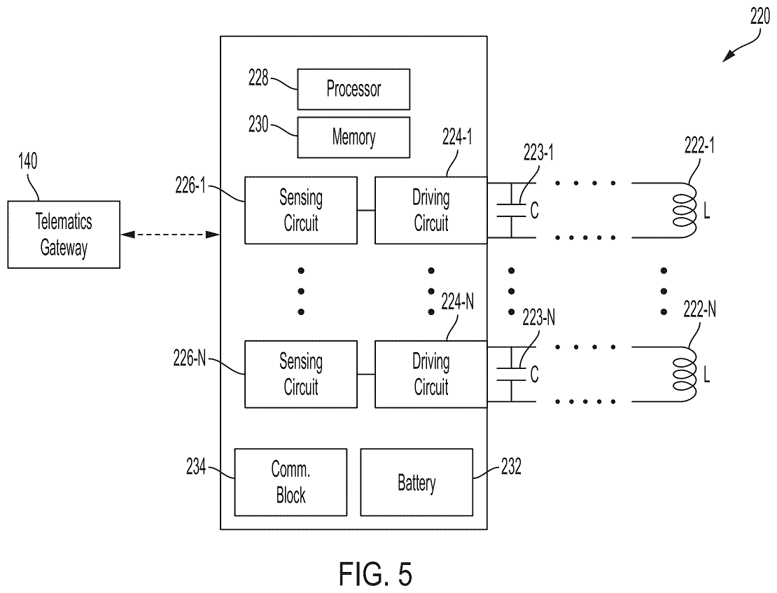

FIG. 5 is a block diagram of the tandem lock-state detector 220 of the tandem locking system 200, according to some embodiments of the present disclosure.

According to some embodiments, the tandem lock-state detector 220 includes a driving circuit 224, a sensing circuit 226, a processor (or processing circuit) 228, a memory 230, and a communication block 234.

The driving circuit 224 is configured to generate a drive signal for driving the inductive element 222. The drive signal is an oscillating signal with a regulated (e.g., constant or substantially constant) oscillation amplitude that causes the inductive element 222 to generate a varying magnetic field. This changing magnetic field in turn induces eddy currents in the surrounding metal structures (e.g., of the lock pin 210, the guide tube 132, the frame of the sliding tandem 122, and the trailer track rails 126), which can be sensed by the sensing circuit 226. The driving circuit 224 ensures that the inductive element 222 operates at the desired frequency and amplitude for accurate parameter measurement. Depending on the application, the frequency of the drive signal may be about 400 KHz to about 1100 KHz.

As shown in FIG. 5, the tandem lock-state detector 220 also includes a capacitor 223 that is coupled in parallel to the inductive element 222. The inductive element 222 and the capacitor 223 together form an LC circuit/resonator that enable the generation of the oscillating drive signal. While FIG. 5 illustrates the capacitor 223 as being external to the driving circuit 224, embodiments of the present disclosure is not limited thereto, and the capacitor 223 may be integrated into the output of the driving circuit 224.

The sensing circuit 226 is configured to sense a parameter corresponding to the inductive elements 222 that is embedded within the lock pins 210, while the inductive elements 222 is being driven with the oscillating drive signal. In some examples, the sensed parameter is the power consumed by the inductive element 222, which correspond to the intensity of the eddy currents induced in the surrounding metal structure near the lock pin 220. The sensing circuit 226 provides the measured parameter value to the processor 228 for analysis and lock/unlock state determination.

In examples in which the sliding tandem 122 has a plurality of lock pins 220-1 to 220-N (where N is an integer greater than one; e.g., N=4), each lock pin 210 may have its own independent driving circuit 224, sensing circuit 226, and capacitor 223. That is, the tandem lock-state detector 220 may include a plurality of capacitors 223-1 to 223-N, a plurality of driving circuits 224-1 to 224-N, and a plurality of sensing circuits 226-1 to 226-N coupled to the inductive elements 222-1 to 222-N.

The processor 228 controls the operations of the various components of the tandem lock-state detector 220, and is configured to process the parameter measurements received from the sensing circuits 226-1 to 226-N to determine the lock/unlock state for each lock pin 210. In some embodiments, the processor 228 is configured to detect the locked state of the lock pin 210 in response to the level of the parameter being greater than a threshold, and to detect the unlocked state of the lock pin 210 in response to the level of the parameter being less than or equal to the threshold. This is due to the fact that, when in a locked state, the inductive element 222 of the lock pin 210 extends out to overlap with the surrounding metal structure near the lock pin 210. As a result, the induced eddy currents increase (e.g., are maximized), which drives up the power consumption of the inductor element 222. In contrast, when in an unlocked state, the inductive element 222 of the lock pin 210 retracts inward to not overlap (or to minimize overlap) with the surrounding metal structure near the lock pin 210. As a result, the induced eddy currents decrease (e.g., are minimized), which drives down the power consumption of the inductor element 222.

However, embodiments of the present disclosure are not limited thereto, and depending on the position of the inductive element 222 relative to the lock pin 210, the logic described above may be reversed. For example, if the inductive element 222 is placed near the front or back ends of the lock pin 210, there may be more eddy currents in the unlocked state than the locked state; in which case, the lock state detection logic will be the reverse of that described above. That is, in such examples, the processor 228 may detect the unlocked state of the lock pin 210 in response to the level of the parameter being greater than a threshold, and may detect the locked state of the lock pin in response to the level of the parameter being less than or equal to the threshold.

The memory 230 is communicatively coupled to the processor 228 and stores the instructions that are executed by the processor 228. The memory 230 may also store the inductor parameter measurements, threshold values, and other relevant data used by the processor 228 to determine the lock/unlock state of the lock pins 210. The memory 230 may include volatile and non-volatile memory components to ensure the retention of data and software even when the system is powered off.

The communication block (or communication circuit) 234 is responsible for managing the communication between the tandem locking system 200 and the telematics gateway module 140. In some examples, the communication block 234 may also communicate directly with the HMI 114 and/or the VCS 112 of the tow vehicle 110. The communication block 234 may supports various communication protocols, such as controller area network (CAN), WiFi, Bluetooth, RS232/485, Ethernet, and/or power line carrier (PLC), to transmit the locking pin state information to the cab driver via the HMI 114 or to an autonomous truck controller. The communication block 234 may also facilitate communication with external servers, such as a remote server 10 on the cloud 20, for remote monitoring and control of the trailer 120.

In some examples, the tandem lock-state detector 220 may also include a battery 232 for powering operations of the tandem lock-state detector 220 when the trailer 120 is not connected to an external power source, such a towing vehicle 110. The battery 232 may be rechargeable and can be charged using various methods, such as through the ABS circuit, a light circuit, a solar panel, wireless power transmission, or power over Ethernet. In addition to, or in lieu of, the battery 232, the tandem lock-state detector 220 may be powered from the ABS circuit, the trailer light circuit, a solar panel, wireless power transmission, power over ethernet, or any other suitable source of electrical power.

As used herein, the term “processor” or “processing circuit” includes any combination of hardware, firmware, and software, employed to process data or digital signals. Processing circuit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). In a processing circuit, as used herein, each function is performed either by hardware configured, i.e., hard-wired, to perform that function, or by more general-purpose hardware, such as a CPU, configured to execute instructions stored in a non-transitory storage medium. A processing circuit may be fabricated on a single printed wiring board (PWB) or distributed over several interconnected PWBs. A processing circuit may contain other processing circuits; for example, a processing circuit may include two processing circuits, an FPGA and a CPU, interconnected on a PWB.

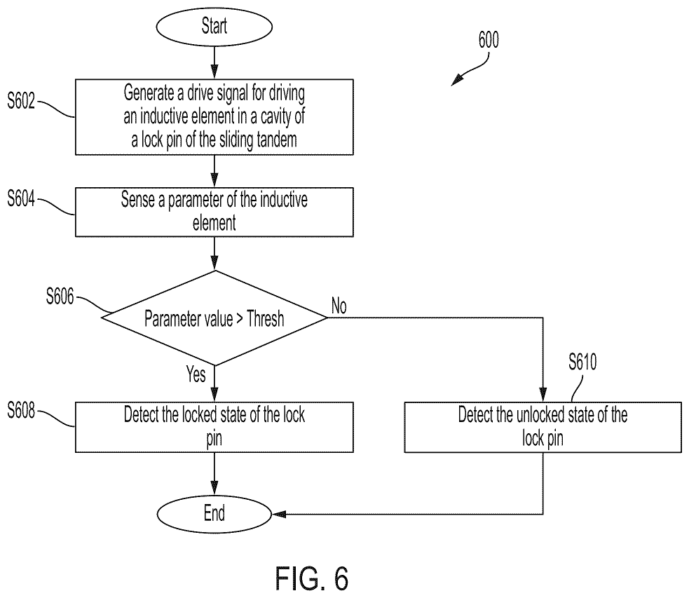

FIG. 6 illustrates a process 600 of detecting a locked state of the sliding tandem 122, according to some embodiments of the present disclosure.

In some embodiments, the tandem lock-state detector 220 generates a drive signal for driving the inductive element 222 in the cavity 212 of the lock pin 210 (S602). The drive signal may be an oscillating signal with a regulated oscillation amplitude.

The tandem lock-state detector 220 also senses a parameter of the inductive element (S604). The parameter may be the power consumption of the inductive element.

The tandem lock-state detector 220 then detects the locked state or an unlocked state of the lock pin based on a level of the parameter (S606-S610). In some embodiments, the tandem lock-state detector 220 compares the level of the parameter with a threshold (S606). When the level of the parameter is greater than the threshold, the tandem lock-state detector 220 detects the locked state of the lock pin (i.e., identifies the state of the lock pin as locked; S608). When the level of the parameter is less than equal to the threshold, the tandem lock-state detector 220 detects the unlocked state of the lock pin (i.e., identifies the state of the lock pin as unlocked; S610).

However, embodiments of the present disclosure are not limited thereto, and depending on the position of the inductive element 222 relative to the lock pin 210, the logic described above with respect to S606-S610 may be reversed. For example, if the inductive element 222 is placed near the front or back ends of the lock pin 210, there may be more eddy currents in the unlocked state than the locked state; in which case, the lock state detection logic will be the reverse of that described above. That is, in such examples, the tandem lock-state detector 220 may detect the unlocked state of the lock pin 210 in response to the level of the parameter being greater than a threshold, and may detect the locked state of the lock pin in response to the level of the parameter being less than or equal to the threshold.

As described herein, the tandem locking system 200 facilitates the automation of the tandem positioning mechanism by obviating the need to visually inspect the locking pins 210 of the sliding tandem 122 before, during, and after a tandem repositioning event. The state information gathered by the tandem lock-state detector 220 may also be used to detect incidents of inadvertent unlocking of the tandem 122, which enables the flagging of this potential safety issue to the driver and/or dispatch. Some embodiments of the present disclosure leverage magnetic principals and utilize the existing mechanical structures as the sensing element and target. For example, the sensing element may be the inductive element embedded within the locking pin 210 and the target may be the metallic structure already in place to guide/contain the sliding locking pin 210.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

While this invention has been described in detail with particular references to exemplary embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims and equivalents thereof.

The present invention is not to be limited in scope by the specific embodiments described herein. Indeed, other various embodiments of and modifications to the present invention, in addition to those described herein, may be apparent to those of ordinary skill in the art from the foregoing description and accompanying drawings. Thus, such other embodiments and modifications are intended to fall within the scope of the present invention. Further, although the present invention has been described herein in the context of a particular implementation in a particular environment for a particular purpose, those of ordinary skill in the art may recognize that its usefulness is not limited thereto and that the present invention may be beneficially implemented in any number of environments for any number of purposes. Accordingly, the claims set forth below should be construed in view of the full breadth and spirit of the present invention as described herein and equivalents thereof.

What is claimed is:

1. A tandem lock-state detector of a vehicle having a sliding tandem, the tandem lock-state detector comprising:
an inductive element in a cavity of a lock pin of the sliding tandem;
a driving circuit configured to generate a drive signal for driving the inductive element;
a sensing circuit configured to sense a parameter of the inductive element; and
a processor configured to detect a locked state or an unlocked state of the lock pin based on a level of the parameter.

2. The tandem lock-state detector of claim 1, further comprising a capacitor electrically coupled in parallel to the inductive element.

3. The tandem lock-state detector of claim 1, wherein the drive signal is an oscillating signal with a regulated oscillation amplitude.

4. The tandem lock-state detector of claim 1, wherein the parameter is a power consumed by the inductive element.

5. The tandem lock-state detector of claim 1, wherein the cavity of the lock pin is exposed to an outside of the lock pin and is configured to accommodate the inductive element, and
wherein the lock pin has a passageway for accommodating conductive wires from the driving circuit to the inductive element.

6. The tandem lock-state detector of claim 1, wherein the inductive element extends along a longitudinal direction of the locking pin.

7. The tandem lock-state detector of claim 1, wherein the lock pin is configured to extend through a hole of the sliding tandem in the locked state and to be retracted from the hole in the unlocked state.

8. The tandem lock-state detector of claim 1, wherein the inductive element is positioned in the lock pin to overlap, in a plan view, frame rails of the sliding tandem in the locked state and to not overlap, in the plan view, the frame rails of the sliding tandem in the unlocked state.

9. The tandem lock-state detector of claim 8, wherein eddy currents induced in metal surrounding the lock pin by magnetic field lines extending from the inductive element in the locked state are greater in intensity than those induced in the metal surrounding the lock pin by the magnetic field lines in the unlocked state.

10. The tandem lock-state detector of claim 1, wherein the processor is configured to detect the locked state of the lock pin in response to the level of the parameter being greater than a threshold, and to detect the unlocked state of the lock pin in response to the level of the parameter being less than or equal to the threshold.

11. The tandem lock-state detector of claim 1, wherein the lock pin is coupled to an actuator configured to move the lock pin along a transverse direction of the sliding tandem and through a guide tube and a hole of the sliding tandem, the guide tube surrounding the hole.

12. A tandem locking system of a vehicle having a sliding tandem, comprising:
a lock pin configured to lock the sliding tandem to a trailer frame of the vehicle;
a tandem lock-state detector comprising:
an inductive element in a cavity of the lock pin;
a driving circuit configured to generate a drive signal for driving the inductive element;
a sensing circuit configured to sense a parameter of the inductive element; and
a processor configured to detect a locked state or an unlocked state of the lock pin based on a level of the parameter.

13. The tandem locking system of claim 12, wherein the drive signal is an oscillating signal with a regulated oscillation amplitude, and
wherein the parameter is a power consumed by the inductive element.

14. The tandem locking system of claim 12, further comprising:
an actuator coupled to the lock pin and configured to move the lock pin through a guide tube of the sliding tandem in response to a user input,
wherein the actuator comprises at least one of a rotating shaft actuator, an air bag actuator, or a lever arm actuator.

15. The tandem locking system of claim 12, wherein the lock pin is configured to extend through a hole of the sliding tandem in the locked state and to be retracted from the hole in the unlocked state, and
wherein the inductive element is positioned in the lock pin to overlap, in a plan view, frame rails of the sliding tandem in the locked state and to not overlap, in the plan view, the frame rails of the sliding tandem in the unlocked state.

16. The tandem locking system of claim 12, wherein eddy currents induced in metal surrounding the lock pin by magnetic field lines extending from the inductive element in the locked state are greater in intensity than those induced in the metal surrounding the lock pin by the magnetic field lines in the unlocked state, and
wherein the processor is configured to detect the locked state of the lock pin in response to the level of the parameter being greater than a threshold, and to detect the unlocked state of the lock pin in response to the level of the parameter being less than or equal to the threshold.

17. A method of detecting a locked state of a sliding tandem of a vehicle, comprising:
generating, by a tandem lock-state detector of the vehicle, a drive signal for driving an inductive element in a cavity of a lock pin of the sliding tandem;
sensing, by the tandem lock-state detector, a parameter of the inductive element; and
detecting, by the tandem lock-state detector, the locked state or an unlocked state of the lock pin based on a level of the parameter.

18. The method of claim 17, wherein the drive signal is an oscillating signal with a regulated oscillation amplitude, and
wherein the parameter is a power consumed by the inductive element.

19. The method of claim 17, wherein the detecting the locked state or the unlocked state comprises:
detecting the locked state of the lock pin in response to the level of the parameter being greater than a threshold.

20. The method of claim 17, wherein the detecting the locked state or the unlocked state comprises:
detecting the unlocked state of the lock pin in response to the level of the parameter being less than or equal to a threshold.
